(19) United States
(12) Patent Application Publication
(10) Pub. No.: US 2010/0123212 A1
(43) Pub. Date: May 20, 2010

(54) Semiconductor device and method of manufacturing the same

(75) Inventors: Jin-Hyuk Chung, Seoul (KR); Hongkyu Hwang, Hwaseong-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/592,024

(22) Filed: Nov. 18, 2009

(30) Foreign Application Priority Data
Nov. 19, 2008 (KR) 10-2008-0115201

(51) Int. Cl. H01L 23/525

(52) U.S. Cl. 257/529; 257/E23.149

(57) ABSTRACT

Provided are a semiconductor device and a method of manufacturing a semiconductor device. The semiconductor device may include first and second conductive lines separated from each other on a semiconductor substrate; a fuse line on the first and second conductive lines; a first conductive via between the fuse line and the first conductive line and a second conductive via between the fuse line and the second conductive line; and a dummy conductive via disposed between the first and second conductive vias, the dummy conductive via being connected to the fuse line so that a portion of the dummy conductive via is removed together with a portion of the fuse line when the fuse line is cut.

### CROSS-REFERENCE TO RELATED APPLICATIONS

This U.S. non-provisional patent application claims priority under 35 U.S.C. §119 of Korean Patent Application No. 2008-0115201, filed in the Korean Intellectual Property Office on Nov. 19, 2008, the entire contents of which are herein incorporated by reference.

### BACKGROUND

The exemplary embodiments described herein relate to semiconductor devices and methods of manufacturing the same, and more particularly, to semiconductor devices including a fuse and methods of manufacturing the same.

As integration of a semiconductor device, for example, a semiconductor memory device, increases, it becomes difficult to obtain a good device in a manufacturing process of the device. The use of redundancy cells has been adopted as a means to solve the problem of failed cells. A redundancy cell can be substituted for a failed memory cell generated in a semiconductor manufacturing process. Accordingly, a product yield can be improved.

After a semiconductor manufacturing process is finished, a failed memory cell is identified by a quality test. A redundancy circuit and a redundancy memory cell can be substituted for a failed memory cell using a fuse electrically connected to the failed memory cell.

### SUMMARY

According to one aspect, the inventive concept is directed to a semiconductor device. The semiconductor device may include: a first conductive line and a second conductive line which are separated from each other on a semiconductor substrate; a fuse line disposed over the first conductive line and the second conductive line; a first conductive via disposed between the fuse line and the first conductive line; a second conductive via disposed between the fuse line and the second conductive line; and a dummy conductive via disposed between the first conductive via and the second conductive via and connected to the fuse line so that a portion of the dummy conductive via is removed together with a portion of the fuse line when the fuse line is cut.

The semiconductor device may further include an interlayer insulating layer covering the first conductive via, the dummy conductive via and the second conductive via, wherein the dummy conductive via penetrates the interlayer insulating layer to be in contact with the fuse line.

The dummy conductive via may have the same level as the first conductive via and a quantity of the second conductive via may be one or more.

The semiconductor device may further include a dummy conductive line disposed between the first conductive line and the second conductive line and separated from each of the first conductive line and the second conductive line. The dummy conductive via may be disposed between the fuse line and the dummy conductive line.

The fuse line may include a fuse barrier layer and a fuse conductive layer which are sequentially stacked. The fuse line may include a fuse conductive layer and a fuse barrier layer uniformly covering a bottom surface and a side surface of the fuse conductive layer.

According to another aspect, the present inventive concept is directed to a method of manufacturing a semiconductor device. The method may include: forming a first conductive line and a second conductive line separated from each other on a semiconductor substrate; forming an interlayer insulating layer covering the first conductive line and the second conductive line; forming a first conductive via connected to the first conductive line, a second conductive via connected to the second conductive line and a dummy conductive via disposed between the first conductive via and the second conductive via by penetrating the interlayer insulating layer; forming a fuse line over the interlayer insulating layer, the fuse line being electrically connected to the first conductive via, the second conductive via and the dummy conductive via.

The method may further include irradiating a laser beam to the fuse line over the dummy conductive via to substitute for a failed memory cell.

Irradiating a laser beam to the fuse line may include removing a portion of the dummy conductive via together with a portion of the fuse line.

The method may further include forming a dummy conductive line between the first conductive line and the second conductive line.

### BRIEF DESCRIPTION OF THE FIGURES

The foregoing and other features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a block diagram of a semiconductor device including a fuse device according to an embodiment of the present inventive concept.

FIG. 2 is a perspective view of a fuse device according to an embodiment of the present inventive concept.

FIG. 3 is a cross-sectional view taken along the line of I-I′ of FIG. 2.

FIGS. 4A and 4B are cross-sectional views representing a cut of a fuse line of FIG. 2 and a fuse device after cutting the fuse line, respectively.

FIGS. 5A, 5B and 5C are cross-sectional views illustrating a method of manufacturing a fuse device according to an embodiment of the present inventive concept.

FIG. 6 is a perspective view of a fuse device according to a modified embodiment of the present inventive concept.

FIG. 7 is a cross-sectional view taken along the line II-II′ of FIG. 6.

FIGS. 8A and 8B are cross-sectional views representing a cut of a fuse line of FIG. 6 and a semiconductor device after cutting the fuse line, respectively.

FIGS. 9A, 9B and 9C are cross-sectional views illustrating a method of manufacturing a semiconductor device according to a modified embodiment of the present inventive concept.

FIG. 10 is a view of a memory card including a semiconductor device according to an embodiment or a modified embodiment of the present inventive concept.

FIG. 11 is a block diagram of an electronic device including a semiconductor device according to an embodiment or a modified embodiment of the present inventive concept.

### DETAILED DESCRIPTION OF THE EMBODIMENTS

The present invention will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this description will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present. Like reference numerals refer to like elements throughout the specification.

Spatially relatively terms, such as “beneath,” “below,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented (rotated 90 degrees or at other orientations) and the spatially relative descriptors used herein interpreted accordingly. As used herein, “height” refers to a direction that is generally orthogonal to the faces of a substrate.

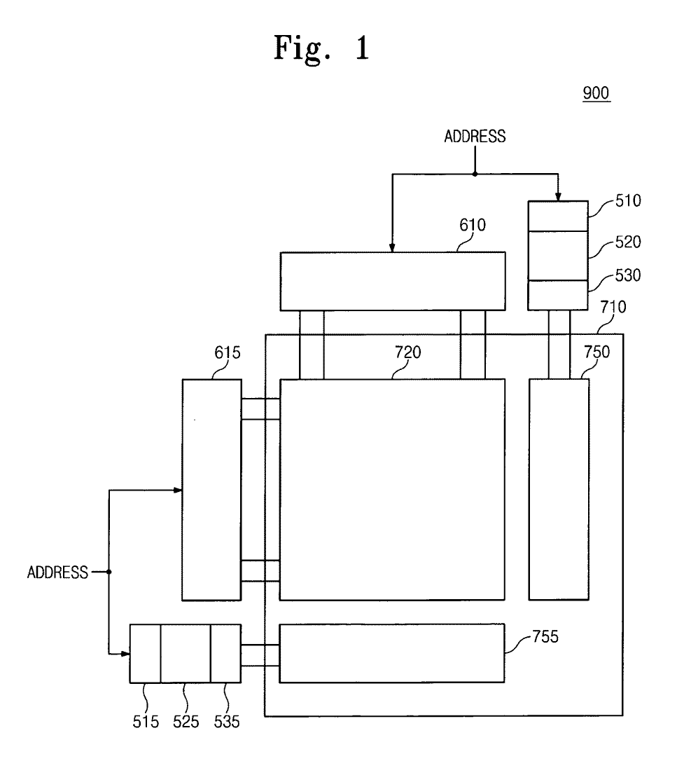

FIG. 1 is a block diagram of a semiconductor device including a fuse device according to an embodiment of the present inventive concept.

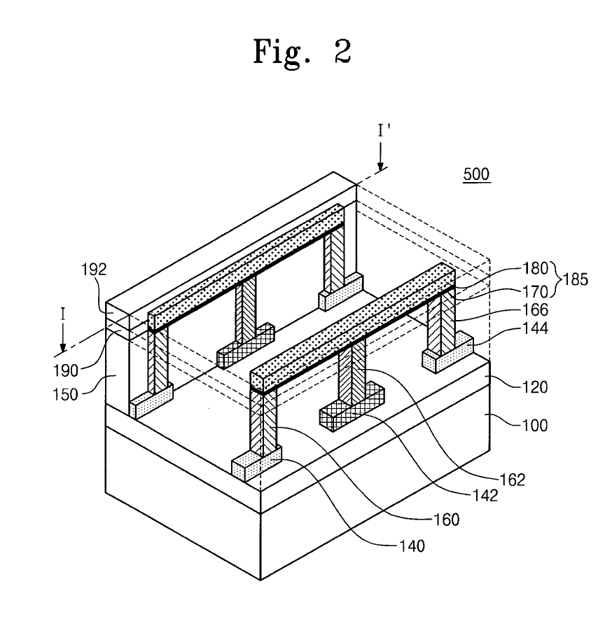

Referring to FIG. 1, a semiconductor device 900 including a fuse device (500 of FIG. 2) according to an embodiment of the present inventive concept may be a semiconductor device (e.g., a DRAM memory device).

The semiconductor device 900 may include a main block 710, column and row address decoders 610 and 615, column and row redundancy decoders 520 and 525, column and row multiplexers 530 and 535 and column and row repair circuits 510 and 515.

The main memory block 710 may include memory cells 720 and column and row redundancy blocks 750 and 755. The memory cells 720 may be accessed by an address signal. The column and row redundancy blocks 750 and 755 may include redundancy memory cells (not shown) that can be substituted for failed memory cells when a failure occurs in the memory cells 720.

The column and row address decoders 610 and 615 can receive and decode an address signal to access a specific cell which the address indicates. The column and row redundancy decoders 520 and 525 can receive and decode an address signal to access a specific cell in the column and row redundancy blocks 750 and 755 which the address indicates when the main memory cell 720 is substituted by a redundancy cell due to a failure. The column and row multiplexers 530 and 535 can select one of a standard redundancy cell and a preliminary redundancy cell in the column and row redundancy blocks 750 and 755. The standard redundancy cell may be a cell for substituting for a failed memory cell. The preliminary redundancy cell is a cell for substituting for the standard redundancy cell when the standard redundancy cell is failed.

The column and row repair circuits 510 and 515 can determine whether accessing the main memory cell 720 or a redundancy cell is accessed, depending on whether a fuse is shorted or not. The column and row repair circuits 510 and 515 may include a fuse device (500 of FIG. 2) according to an embodiment of the present inventive concept.

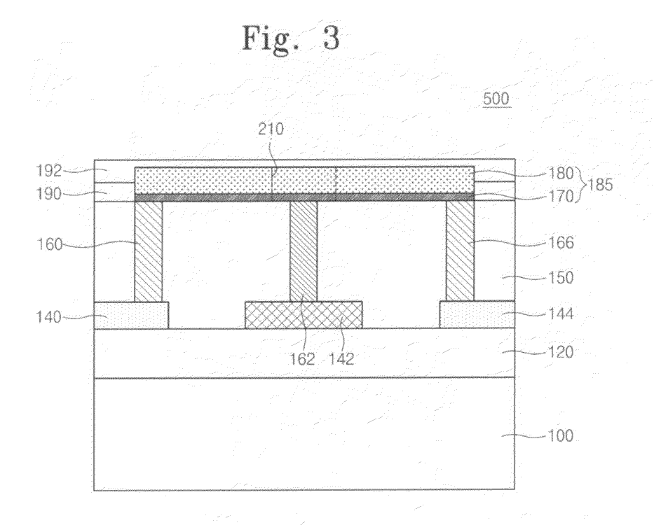

FIG. 2 is a perspective view of a fuse device according to an embodiment of the present inventive concept. FIG. 3 is a cross-sectional view taken along the line of I-I′ of FIG. 2. Referring to FIGS. 2 and 3, a fuse device 500 according to an embodiment of the present inventive concept is described.

The fuse device 500 may include first and second conductive lines 140 and 144 disposed to be separated from each other on a semiconductor substrate 100, a fuse line 185 electrically connecting first and second conductive lines 140 and 144, a first conductive via 160 between the fuse line 185 and the first conductive line 140, a second conductive via 166 between the fuse line 185 and the second conductive line 144 and a dummy conductive via 162 between the first and second conductive vias 160 and 166.

The first and second conductive lines 140 and 144 may be disposed on a first interlayer insulating layer 120 of the semiconductor substrate 100. The first interlayer insulating layer 120 may be a silicon oxide layer. The first interlayer insulating layer 120 may include a conductor (not shown). The conductor may include a conductive plug or an interconnection line.

The first and second conductive lines 140 and 144 are disposed to be separated from each other. The first and second conductive lines 140 and 144 may be at the same level and may have a bar shape. The first conductive line 140 can extend in a specific direction and the second conductive line 144 can extend in an opposite direction of the specific direction. The first and second conductive lines 140 and 144 may be a bit line or a word line. The first and second conductive lines 140 and 144 may include aluminum or copper.

A dummy conductive line 142 may be disposed between the first and second conductive lines 140 and 144. The dummy conductive line 142 may be at the same level as the first and second conductive lines 140 and 144. The dummy conductive line 142 may have a short bar shape compared with the first and second conductive lines 140 and 144. The dummy conductive line 142 may be disposed to be spaced apart from the respective first and second conductive lines 140 and 144. The dummy conductive line 142 can protect a conductor disposed on the first interlayer insulating layer 120 under the dummy conductive line 142 when the fuse line 185 is cut, which can be subsequently performed.

A second interlayer insulating layer 150 may cover the first conductive line 140, the dummy conductive line 142 and the second conductive line 144. The second interlayer insulating layer 150 may be a silicon oxide layer.

The fuse line 185 may be disposed on the second interlayer insulating layer 150. The fuse line 185 may include a fuse barrier layer 170 and a fuse conductive layer 180 that are sequentially stacked. The fuse barrier layer 170 may include titanium or a titanium nitride layer. The fuse conductive layer 180 may include aluminum.

The first conductive via 160 penetrates the second interlayer insulating layer 150 and is disposed between the fuse line 185 and the first conductive line 140 to electrically connect the first conductive line 140 and the fuse line 185. The second conductive via 166 penetrates the second interlayer insulating layer 150 and is disposed between the fuse line 185 and the second conductive line 144 to electrically connect the second conductive line 144 and the fuse line 185. The first and second conductive vias 160 and 166 may include tungsten. The first and second conductive lines 140 and 144 are electrically connected to each other through the fuse line 185.

The dummy conductive via 162 is disposed under the fuse line 185. The dummy conductive via 162 may be disposed under a center of the fuse line 185. The dummy conductive via 162 may be at the same level as the first and second conductive vias 160 and 166. The dummy conductive via 162 may include the same material as the first and second conductive vias 160 and 166. The dummy conductive via 162 may penetrate the second interlayer insulating layer 150 to be disposed between the fuse line 185 and the dummy conductive line 142. The dummy conductive via 162 may be disposed to be separated from the first and second conductive vias 160 and 166. The dummy conductive via 162 and the dummy conductive line 142 may be arranged under the fuse line 185. A top surface of the dummy conductive via 162 and top surfaces of the first and second conductive vias 160 and 166 may be exposed from the second interlayer insulating layer 150. The top surface of the dummy conductive via 162 may be in contact with a bottom surface of the fuse line 185. An oxidation prevention layer 190 may cover a side portion of the fuse line 185. A molding layer 192 may cover the oxidation prevention layer 190 and the fuse line 185.

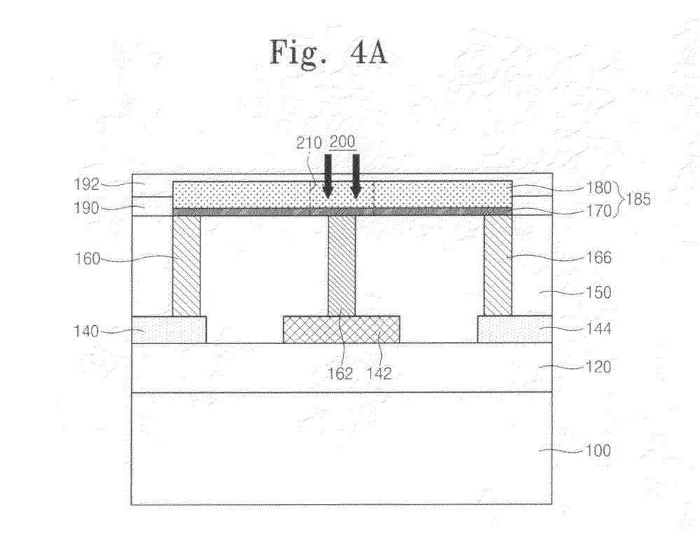

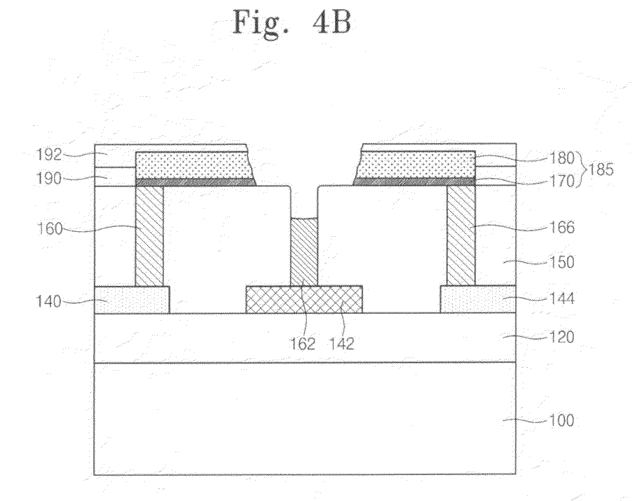

FIGS. 4A and 4B are cross-sectional views illustrating a cut of the fuse line 185 included in the fuse device 500 of FIG. 2 and the fuse device 500 after the fuse line 185 is cut, respectively.

Referring to FIGS. 4A and 4B, the fuse line 185 may be cut by irradiating a laser beam 200 into the fuse line 185 so as to substitute for a failed memory cell. The laser beam 200 may be irradiated into a center 210 of the fuse line 185.

When the fuse line 185 does not have the dummy conductive via 162, the second interlayer insulating layer 150 under the fuse line 185 may be damaged by the laser beam 200 during a cut of the fuse line 185, but the shape of the second interlayer insulating layer 150 can be maintained. Thus, a portion of the fuse barrier layer 170 can remain on the second interlayer insulating layer 150. According to an embodiment of the present inventive concept, the dummy conductive via 162 is a conductor and can be in contact with the fuse line 185. Therefore, a portion of the fuse line 185 in contact with the dummy conductive via 162 can be easily cut together with an upper portion of the dummy conductive via 162 compared with when the dummy conductive via 162 does not exist. The fuse barrier layer 170 disposed between the fuse conductive layer 180 and the dummy conductive via 162 can be completely cut. Thus, residue of the fuse line 185 does not remain between the cut fuse lines 185. Also, when the dummy conductive via 162 and the dummy conductive line 142 are present, a space between the fuse lines 185 does not need to be wide.

Consequently, an uncut phenomenon of the fuse line by a absorption of residue of the fuse line 185, an uncut phenomenon of the fuse line by the remaining fuse barrier layer 170 after cutting the fuse line 185 and a bridge phenomenon of the fuse line by an oxidation of residue of the fuse line 185 can be reduced. Thus, a repair yield of the fuse line can be improved.

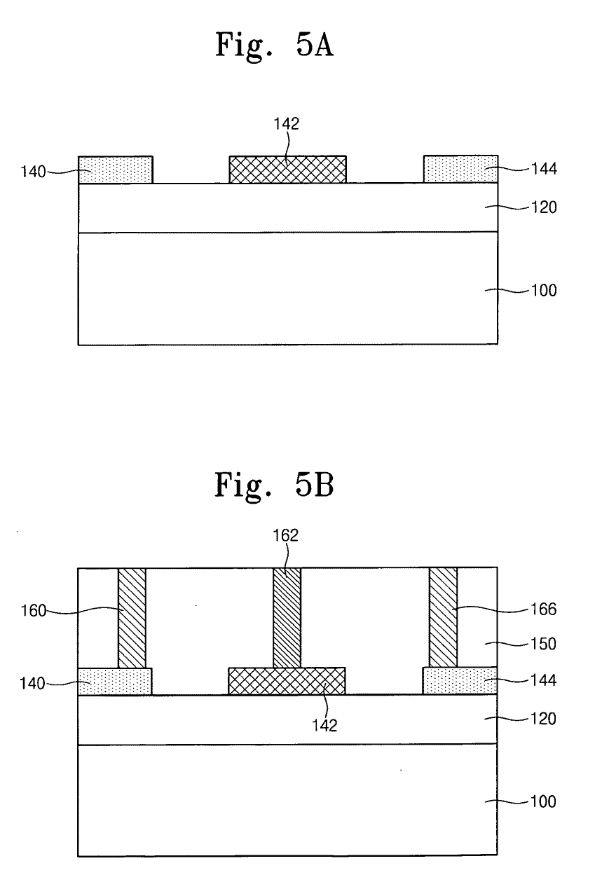

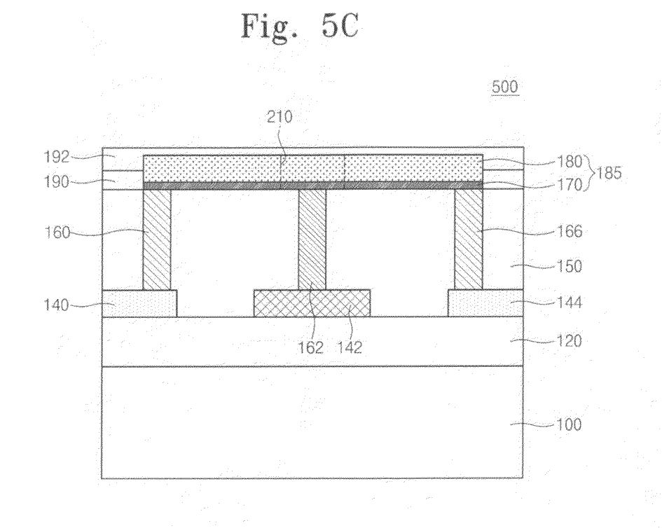

FIGS. 5A, 5B and 5C are cross-sectional views illustrating a method of manufacturing a fuse device according to an embodiment of the present inventive concept.

Referring to FIG. 5A, a first interlayer insulating layer 120 may be formed on a semiconductor substrate 100. The first interlayer insulating layer 120 may, for example, be a silicon oxide layer formed by performing a chemical vapor deposition (CVD) process.

A conductive line deposited on the first interlayer insulating layer 120 may be patterned to form a first conductive line 140, a dummy conductive line 142 and a second conductive line 144. The first and second conductive lines 140 and 144 may, for example, be a bit line or a word line. The first conductive line 140, the dummy conductive line 142 and the second conductive line 144 may, for example, include aluminum or copper.

Referring to FIG. 5B, a second interlayer insulating layer 150 covering the first conductive line 140, the dummy conductive line 142 and the second conductive line 144 may be formed on the first interlayer insulating layer 120. The second interlayer insulating layer 150 may, for example, be a silicon oxide layer.

A first conductive via 160, a dummy conductive via 162 and a second conductive via 166 penetrating the second interlayer insulating layer 150 may be formed. The first conductive via 160, the dummy conductive via 162 and the second conductive via 166 may be formed by performing a chemical vapor deposition (CVD) process. The first conductive via 160, the dummy conductive via 162 and the second conductive via 166 may be, for example, tungsten. A top surface of the first conductive via 160, a top surface of the dummy conductive via 162 and a top surface of the second conductive via 166 may be exposed from the second interlayer insulating layer 150.

Referring to FIG. 5C, a fuse barrier layer 170 and a fuse conductive layer 180 may be formed by patterning conductive layers that are sequentially stacked on the second interlayer insulating layer 150. The fuse barrier layer 170 and the fuse conductive layer 180 may be formed by performing a physical vapor deposition (PVD) or a chemical vapor deposition (CVD) process. The fuse barrier layer 170 may, for example, be titanium or a titanium nitride layer. The fuse conductive layer 180 may include aluminum. The fuse barrier layer 170 and the fuse conductive layer 180 may constitute a fuse line 185.

An oxidation prevention layer 190 covering a side portion of the fuse line 185 may be formed. A molding layer 192 covering the oxidation prevention layer 190 and the fuse line 185 may be formed.

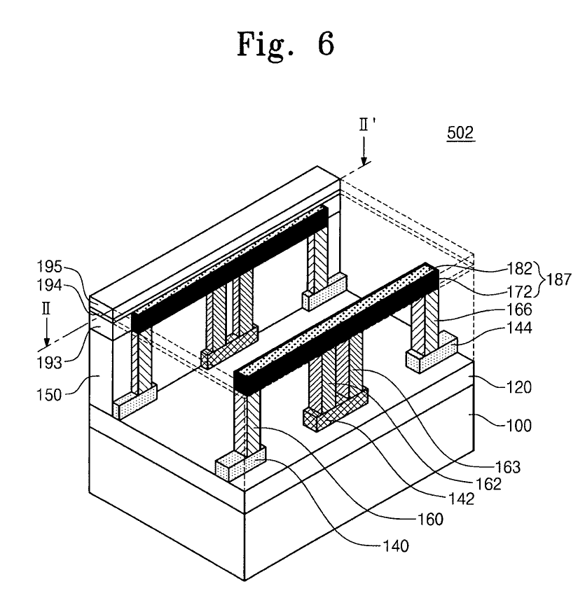

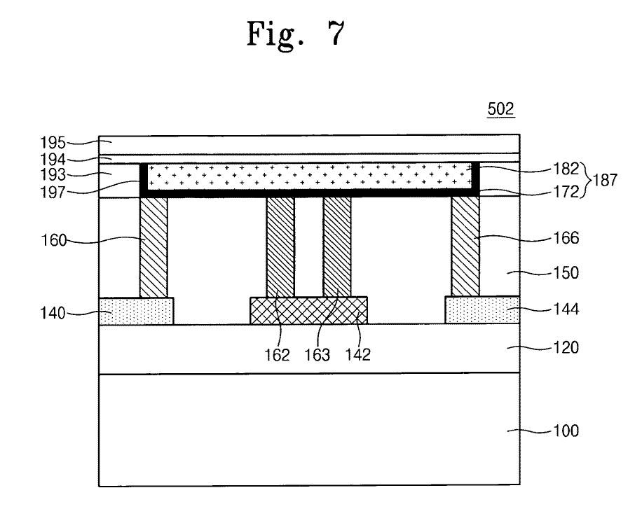

FIG. 6 is a perspective view of a fuse device according to a modified embodiment of the present inventive concept. FIG. 7 is a cross-sectional view taken along the line II-II′ of FIG. 6. A fuse device according to the modified embodiment includes some features similar to features of the fuse device described above. Detailed description of these similar or common features will not be repeated.

Referring to FIGS. 6 and 7, a fuse device 502 according to the modified embodiment of the present inventive concept is described. The fuse device 502 is different from the fuse device (500 of FIG. 2) in the fuse line 187 and the first and second dummy conductive vias 162 and 163.

A third interlayer insulating layer 193 may be disposed on the second interlayer insulating layer 150. The third interlayer insulating layer 193 may include an opening 197. The third interlayer insulating layer 193 may, for example, be a silicon oxide layer. The opening 197 can expose a top surface of the first conductive via 160, a top surface of the first and second dummy conductive vias 162 and 164 and a top surface of the second conductive via 166.

The fuse line 187 may be filled in the opening 197. The fuse line 187 may include a fuse conductive layer 182 and a fuse barrier layer 172. The fuse barrier layer 172 can uniformly cover a bottom surface and a side surface of the fuse conductive layer 182. The fuse barrier layer 172 may, for example, be tantalum or a tantalum nitride layer.

The first and second dummy vias 162 and 163 are disposed under the fuse line 187. The first and second dummy vias 162 and 163 may be disposed under a center of the fuse line 187. The first and second dummy vias 162 and 163 may penetrate the second interlayer insulating layer 150 to be disposed between the fuse line 187 and a dummy conductive line 142. A surface of the first and second dummy conductive vias 162 and 163 and surfaces of the first and second conductive vias 160 and 166 may be exposed from the second interlayer insulating layer 150. The first and second dummy vias 162 and 163 may be disposed between the first and second conductive vias 160 and 166. The first and second dummy conductive vias 162 and 163 may be adjacent to each other.

An oxidation prevention layer 194 can cover the fuse line 187 and the third interlayer insulating layer 193. The oxidation prevention layer 194 can prevent an oxidation of the fuse conductive layer 182. A molding layer 195 can cover the oxidation prevention layer 194.

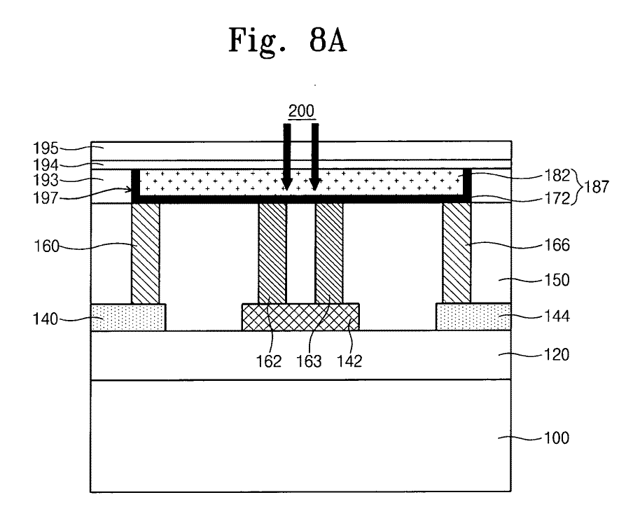

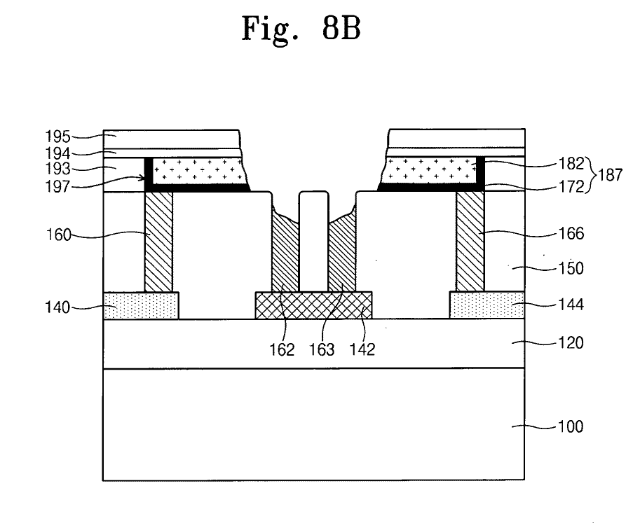

A cut of the fuse line 187 included in the fuse device 502 and the fuse device 502 after cutting the fuse line 187 are now described. FIGS. 8A and 8B are cross-sectional views representing a cut of a fuse line of FIG. 6 and a semiconductor device after cutting the fuse line, respectively.

Referring to FIGS. 8A and 8B, the fuse line 187 may be cut by irradiating a laser beam 200 into the fuse line 187 to substitute for a failed memory cell. The laser beam 200 may be irradiated into a center of the fuse line 187.

According to the modified embodiment of the present inventive concept, the use of a plurality of dummy conductive vias 162 and 163, instead of a single dummy conductive via allows for improved ease of removal, i.e., interruption, of the fuse line 187.

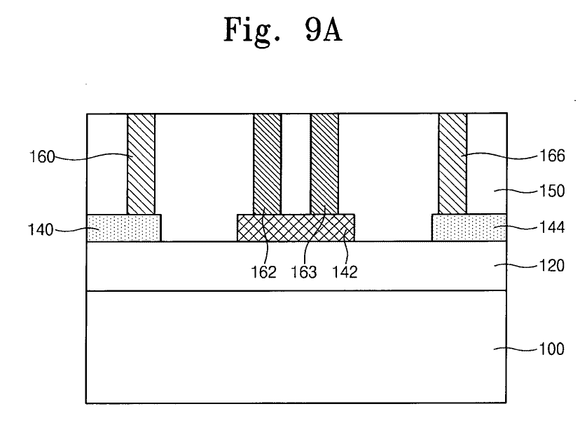

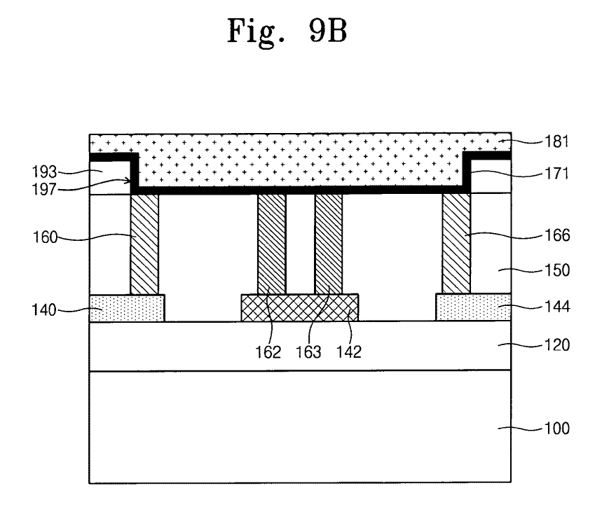

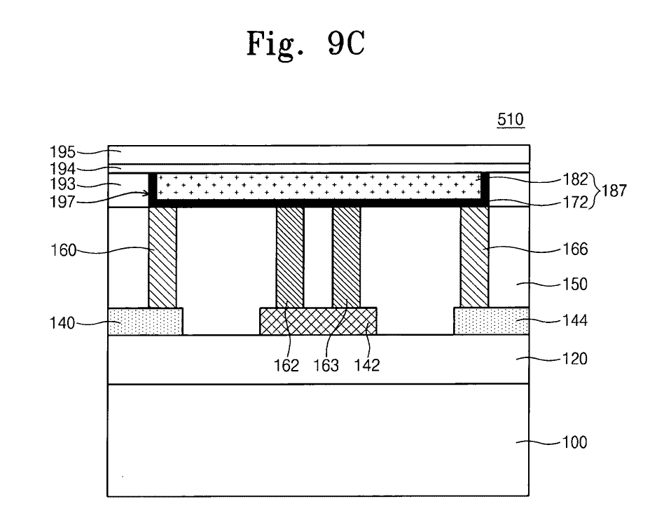

FIGS. 9A, 9B and 9C are cross-sectional views illustrating a method of manufacturing a semiconductor device according to a modified embodiment of the present inventive concept. The method of manufacturing a semiconductor device according to the modified embodiment includes features similar to those of the method of manufacturing a semiconductor device according to the embodiment described above. Detailed description of common features will not be repeated.

Referring to FIG. 9A, a first interlayer insulating layer 120 may be formed on a semiconductor substrate 100. A conductive layer deposited on the first interlayer insulating layer 120 may be patterned to form a first conductive line 140, a dummy conductive line 142 and a second conductive line 144.

A second interlayer insulating layer 150 covering the first conductive line 140, the dummy conductive line 142 and the second conductive line 144 may be formed on the first interlayer insulating layer 120. A first conductive via 160, a first dummy conductive via 162, a second dummy conductive via 163 and a second conductive via 166 penetrating the second interlayer insulating layer 150 may be formed. A surface of the first and second dummy conductive vias 162 and 163 and surfaces of the first and second conductive vias 160 and 166 may be exposed from the second interlayer insulating layer 150.

Referring to FIG. 9B, a third interlayer insulating layer 193 having an opening 197 may be formed on the second interlayer insulating layer 150. The opening 197 can expose a top surface of the first conductive via 160, a top surface of the first and second dummy conductive vias 162 and 163 and a top surface of the second conductive via 166.

A preliminary fuse barrier layer 171 may be formed on the third interlayer insulating layer 193. The preliminary fuse barrier layer 171 may be uniformly formed on a bottom surface of the opening 197 and a side surface of the opening 197. The preliminary fuse barrier layer 171 may be formed by performing a physical vapor deposition or a chemical vapor deposition. The preliminary fuse barrier layer 171 may be tantalum or a tantalum nitride layer.

A preliminary fuse conductive layer 181 can be formed on the preliminary barrier layer 171 to fill the opening 197. The preliminary fuse conductive layer 181 may be formed by performing an electroplating process or an electroless plating process. The preliminary fuse conductive layer 181 may include copper.

Referring to FIG. 9C, the preliminary fuse conductive layer 181 and the preliminary fuse barrier layer 171 may be planarized down to the top surface of the third interlayer insulating layer 193 to form a fuse conductive layer 182 and a fuse barrier layer 172. The planarization process may be a chemical mechanical polishing (CMP) process. The fuse conductive layer 182 and the fuse barrier layer 172 can constitute a fuse line 187.

An oxidation prevention layer 194 covering the fuse line 187 and the third interlayer insulating layer 193 may be formed. A molding layer 195 may be formed on the oxidation prevention layer 194.

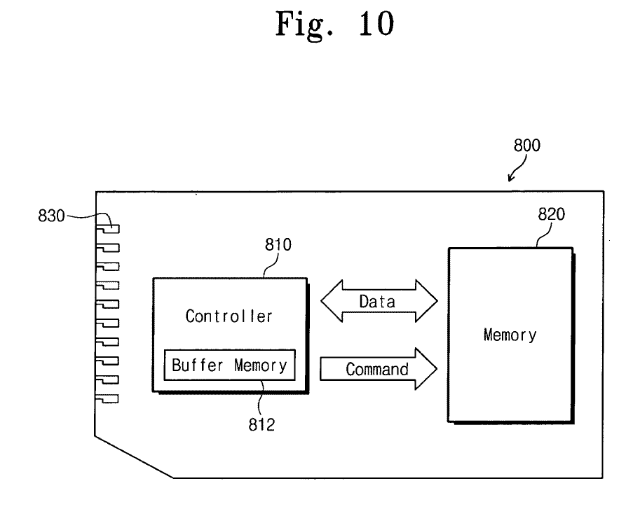

FIG. 10 is a view of a memory card including a semiconductor device according to an embodiment or a modified embodiment of the present inventive concept.

Referring to FIG. 10, a memory card system 800 including the fuse device (500, 502) according to the embodiment or the modified embodiment of the present inventive concept is described. The memory card system 800 may include a controller 810, a memory 820 and an interface 830.

The memory 820 may include the fuse device (500, 502) according to an embodiment or a modified embodiment of the present inventive concept. The memory 820 may be used to store a command being executed by the controller 810 and/or user data. The controller 810 and the memory 820 may be configured to transmit and receive the command and/or data. The interface 830 may implement input/output of data with an external device. The controller 810 may include a buffer memory 812. The buffer memory 812 may be used to temporarily store data to be stored in the memory 820 or read by the memory 820. The buffer memory 812 may be used to temporarily store data processed in the controller 810. The buffer memory 812 may be, for example, a dynamic random access memory (DRAM) or a static random access memory (SRAM). The present inventive concept can be applied to the buffer memory 812.

The memory card system 800 may be, for example, a multimedia card (MMC), a secure digital card (SD) or a portable data storage device.

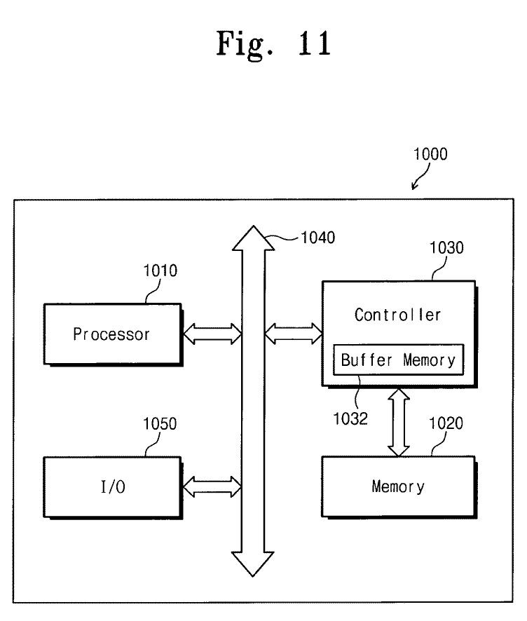

FIG. 11 is a block diagram of an electronic device including a semiconductor device according to an embodiment or a modified embodiment of the present inventive concept.

Referring to FIG. 11, an electronic device 1000 including the fuse device (500, 502) according to an embodiment or a modified embodiment of the present inventive concept is described. The electronic device 1000 may include a processor 1010, a memory 1020, a controller 1030 and an input/output device 1040. The memory 1010 may include the fuse device (500, 502) according to the embodiment or the modified embodiment of the present inventive concept. The processor 1010, the controller 1030 and the input/output device 1050 can be connected to each other through a bus 1040. The processor 1010 can control overall operations of the controller 1030. The controller 1030 may include a buffer memory 1032. The buffer memory 1032 may be, for example, a dynamic random access memory (DRAM) or a static random access memory (SRAM). The memory 1020 may be used to store data being accessed through the controller 1030. It is apparent to those of reasonable skill in the art that additional circuits and control signals may be provided for a concrete embodiment and a concrete modification of the invention.

The electronic device 1000 can be used in a computer system, a wireless communication device such as PDA, a lap to computer, a portable computer, a web tablet, a wireless phone, a cellular phone, a digital music player, a MP3 player, a navigation, a solid state disk (SSD), a home appliance or all devices which can transmit data and receive data in a wireless communication environment.

According to an embodiment of the present inventive concept, an uncut phenomenon of the fuse line by an absorption of residue of the fuse line 185, an uncut phenomenon of the fuse line by the remaining fuse barrier layer 170 after cutting the fuse line 185 and a bridge phenomenon of the fuse line by an oxidation of residue of the fuse line 185 can be reduced. Thus, a repair yield of the fuse line can be improved.

1. A semiconductor device comprising:
a first conductive line and a second conductive line which are separated from each other on a semiconductor substrate;
a fuse line disposed over the first conductive line and the second conductive line;
a first conductive via disposed between the fuse line and the first conductive line;
a second conductive via disposed between the fuse line and the second conductive line; and
a dummy conductive via disposed between the first conductive via and the second conductive via and connected to the fuse line so that a portion of the dummy conductive via is removed together with a portion of the fuse line when the fuse line is cut.

2. The semiconductor device of claim 1, further comprising an interlayer insulating layer covering the first conductive via, the dummy conductive via and the second conductive via, wherein the dummy conductive via penetrates the interlayer insulating layer to be in contact with the fuse line.

3. The semiconductor device of claim 1, wherein the dummy conductive via has the same level as the first conductive via and a quantity of the second conductive via is one or more.

4. The semiconductor device of claim 1, further comprising a dummy conductive line disposed between the first conductive line and the second conductive line and separated from each of the first conductive line and the second conductive line.

5. The semiconductor device of claim 4, wherein the dummy conductive via is disposed between the fuse line and the dummy conductive line.

6. The semiconductor device of claim 1, wherein the fuse line comprises a fuse barrier layer and a fuse conductive layer which are sequentially stacked.

7. The semiconductor device of claim 1, wherein the fuse line comprises a fuse conductive layer and a fuse barrier layer uniformly covering a bottom surface and a side surface of the fuse conductive layer.

8-11. (canceled)
